(19) United States
(12) Patent Application Publication
(10) Pub. No.: US 2026/0246262 A1
(43) Pub. Date: Aug. 20, 2026

(54) Overcurrent Protection for Bidirectional Power Semiconductor Devices

(71) Applicant: IDEAL POWER INC., Austin, TX (US)

(72) Inventors: Seyed Milad Tayebi, Austin, TX (US); Ruiyang Yu, Austin, TX (US)

(73) Assignee: IDEAL POWER INC., Austin, TX (US)

(21) Appl. No.: 19/464,773

(22) Filed: Jan. 30, 2026

Related U.S. Application Data
(60) Provisional application No. 63/759,314, filed on Feb. 17, 2025.

(51) Int. Cl. H02H 9/02; H02H 1/00

(52) U.S. Cl. CPC H02H 9/025; H02H 1/003

(57) ABSTRACT

Overcurrent protection for bidirectional power semiconductor devices. At least one example is a method of operating a switch assembly, the method comprising: conducting a forward load current from an upper terminal of the switch assembly, then through a power semiconductor device, then through a lower cascode FET, and then through a lower terminal of the switch assembly; and simultaneously driving a forward sense current from a lower gate driver through the power semiconductor device; and thereafter interrupting, by the lower gate driver, the forward load current by de-asserting a gate of the lower cascode FET, the interrupting responsive to a voltage used to drive the forward sense current exceeding a predetermined threshold; and interrupting, by the lower gate driver, a reverse sense pathway of an upper gate driver.

### CROSS-REFERENCE TO RELATED APPLICATIONS

This application claims the benefit of U.S. Provisional Application No. 63/759,314, filed on Feb. 17, 2025. The entire disclosure of the application referenced above is incorporated herein by reference.

### BACKGROUND

A power semiconductor device is a semiconductor device that is specifically designed to handle and control high voltages and currents in electrical circuits. Power semiconductor devices are used in power electronics, which is the field of engineering that deals with the conversion, control, and conditioning of electric power, such as in control of industrial machinery and renewable energy systems.

One failure mode of power semiconductor devices is known as “desaturation.” That is, when excess current is carried through a power semiconductor device, the device may be unable to maintain a low on-state voltage drop, which leads to desaturation. In related-art devices and systems, a gate driver provides voltage and currents to turn on and turn off the device, and the gate driver may be charged with sensing when desaturation occurs. When desaturation occurs, the gate drive may make the power semiconductor device non-conductive to reduce or avoid damage to itself or downstream devices.

### SUMMARY

At least one example is a method of operating a switch assembly, the method comprising: conducting a forward load current from an upper terminal of the switch assembly, then through a power semiconductor device, then through a lower cascode FET, and then through a lower terminal of the switch assembly; and simultaneously driving a forward sense current from a lower gate driver through the power semiconductor device; and thereafter interrupting, by the lower gate driver, the forward load current by de-asserting a gate of the lower cascode FET, the interrupting responsive to a voltage used to drive the forward sense current exceeding a predetermined threshold; and interrupting, by the lower gate driver, a reverse sense pathway of an upper gate driver.

In the example method, driving the forward sense current may comprise driving the forward sense current from the lower gate driver through an upper transistor, then through the power semiconductor device, then through the lower cascode FET, and then back to the lower gate driver. The example method may further comprise blocking the forward sense current using the upper transistor. The upper transistor may be at least one selected from a group comprising: a junction transistor; an integrated gate bipolar junction transistor.

In the example method, interrupting the forward load current and interrupting the reverse sense pathway may be based on the lower gate driver de-asserting a single gate terminal.

In the example method, the power semiconductor device may be a double-sided double-base bipolar junction transistor. Conducting the forward load current may further comprise driving charge carriers into a drift region of the bipolar junction transistor. Driving charge carriers may further comprise injecting charge carriers through an upper base or a lower base of the bipolar junction transistor.

The example method may further comprise: conducting a reverse load current from the lower terminal of the switch assembly, then through the lower cascode FET, then through the power semiconductor device, then through an upper cascode FET, and then through the upper terminal of the switch assembly; and simultaneously driving a reverse sense current from an upper gate-driver through the power semiconductor device; and thereafter interrupting, by the upper gate driver, the reverse load current by de-asserting a gate of the upper cascode FET, the interrupting the reverse load current responsive to a voltage used to drive the reverse sense current exceeding a predetermined threshold; and interrupting, by the upper gate driver, a forward sense pathway of the upper gate driver. Driving the reverse sense current may comprise driving the reverse sense current from the upper gate driver, then through a lower transistor, then through the lower cascode FET, then through power semiconductor device, then through the upper cascode FET, and then back to the upper gate driver. The example method may further comprise blocking the reverse sense current using the lower transistor. Interrupting the reverse load current and interrupting the forward sense pathway may be based on the upper gate-driver de-asserting a single gate terminal.

Another example is a switch assembly comprising: an upper terminal, a lower terminal, and a control input; an upper cascode FET defining a first lead coupled to the upper terminal, a second lead, and a gate; a lower cascode FET defining a first lead coupled to the lower terminal, a second lead, and a gate; a power semiconductor device coupled between the second leads and having a control lead; and a driver. The driver may comprise: an upper transistor defining a first lead coupled to the upper terminal, a second lead, and a base; a lower transistor defining a first lead coupled to the lower terminal, a second lead, and a base; an upper gate-driver having a drive-in terminal, a drive terminal coupled to both the gate of the upper-cascode FET and the base of the upper transistor, and a sense terminal coupled to the second lead of the lower transistor, the upper gate-driver is configured to, responsive to assertion of its drive-in terminal, drive a reverse sense current through the lower transistor and the power semiconductor device; the upper gate-driver may be configured to, responsive to an overcurrent condition detected using the reverse sense current, de-assert its drive terminal to make the upper-cascode FET and the upper transistor non-conductive; a lower gate-driver having a drive-in terminal, a drive terminal coupled to both the gate of the lower-cascode FET and the base of the lower transistor, and a sense terminal coupled to the second lead of the lower transistor, the lower gate-driver may be configured to, responsive to assertion of its drive-in terminal, drive a forward sense current through the upper transistor and power semiconductor device; and the lower gate-driver may be configured to, responsive to an overcurrent condition detected using the forward sense current, de-assert its drive terminal to make the lower cascode FET and the lower transistor non-conductive.

In the example switch assembly, the power semiconductor device may be a double-sided double-base bipolar junction transistor. The upper transistor may be at least one selected from a group comprising: a junction transistor; an integrated gate bipolar junction transistor.

In the example switch assembly, the lower transistor may be at least one selected from a group comprising: a junction transistor; an integrated gate bipolar junction transistor.

The example switch assembly may further comprise: an overcurrent terminal defined by the upper gate-driver; an overcurrent terminal defined by the lower gate-driver; a controller coupled to the control input, the control lead of power semiconductor device, the drive-in terminals, and the overcurrent terminals. The controller may be configured to: responsive to assertion of the control input and for a first applied voltage across the upper terminal and lower terminal, assert the drive-in terminals to arrange upper cascode FET and lower cascode FET for conduction of forward load current; and responsive to assertion of the overcurrent terminal of the lower gate-driver, de-assert the drive-in terminals.

In the example switch assembly, the controller may be further configured to: responsive to assertion of the control input and for a second applied voltage across the upper terminal and lower terminal, opposite the first applied voltage, assert the drive-in terminals to arrange upper cascode FET and lower cascode FET for conduction of reverse load current; and responsive to assertion of an overcurrent terminal of the upper gate-driver, de-assert the drive-in terminals.

In the example switch assembly, the upper cascode FET, the lower cascode FET, and the power semiconductor device may be co-packaged.

### BRIEF DESCRIPTION OF THE DRAWINGS

For a detailed description of example embodiments, reference will now be made to the accompanying drawings.

FIG. 1 shows an example switch assembly.

FIG. 2 shows an example bidirectional switch.

FIGS. 3A-3G show a double-sided double-base bipolar junction transistor of PNP construction in shorthand form, with example external electrical connections, to illustrate several operational states.

FIG. 4 shows a partial electrical schematic of an example switch assembly.

FIG. 5A shows a partial electrical schematic of an example switch assembly.

FIG. 5B shows a partial electrical schematic of an example switch assembly.

FIG. 5C shows a partial electrical schematic of an example switch assembly.

FIG. 6 shows a partial electrical schematic of an example switch assembly.

FIG. 7 shows a partial block diagram, partial electrical schematic, of an example switch assembly.

FIG. 8 shows an example method.

### DEFINITIONS

Various terms are used to refer to particular system components. Different companies may refer to a component by different names – this document does not intend to distinguish between components that differ in name but not function. In the following discussion and in the claims, the terms “including” and “comprising” are used in an open-ended fashion, and thus should be interpreted to mean “including, but not limited to… .” Also, the term “couple” or “couples” is intended to mean either an indirect or a direct connection. Thus, if a first device is coupled to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” in reference to a recited parameter shall mean the recited parameter plus or minus ten percent (+/- 10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

“FET” shall mean a field effect transistor, such as a junction-gate FET (JFET) or metal-oxide-silicon FET (MOSFET).

“Closing” in reference to an electrically-controlled switch (e.g., a FET) shall mean making the electrically-controlled switch conductive. For example, closing a FET used as an electrically-controlled switch may mean driving the FET to the fully conductive state.

“Opening” in reference to an electrically-controlled switch (e.g., a FET) shall mean making the electrically-controlled switch non-conductive. Leakage current shall not negate the status of an electrically-controlled switch being non-conductive.

“DSDB-BJT” shall mean a double-sided double-base (DSDB) bipolar junction transistor (BJT) having base and collector-emitter on a first side of a drift region, and a distinct and separate base and collector-emitter on a second side of the drift region, opposite the first side. The drift region may be continuous, or the drift region may comprise an upper drift region associated with the upper base and upper collector-emitter, and a lower drift region associated with the lower base and lower collector-emitter.

“Collector-emitter” of a bipolar junction transistor shall mean a region of the bipolar junction transistor through which main load current flows. For purposes of this specification and claims, the designation as a collector-emitter is independent of the underlying device physics within the bipolar junction transistor. For example, for a double-sided double-base PNP transistor, the main load current may flow from an upper P-type region, through the bulk N-type drift region, and then out the lower P-type region, and when so used the upper P-type region and the lower P-type region are considered collector-emitters. However, in other cases, such as described in co-pending and commonly assigned U.S. App. 18/483,939 filed Oct. 10, 2023 and titled “Methods and Systems of Operating a PNP Bi-Directional Double-Base Bipolar Junction Transistor,” the main load current may flow from an upper N-type region, through the bulk N-type drift region, and then through the lower N-type region, and when so used the upper and lower N-type regions are considered collector-emitters.

“Base” of a bipolar junction transistor shall mean a region of the bipolar junction transistor through which control current flows, the control current distinct from the main load current. For purposes of this specification and claims, the designation as a base is independent of the underlying device physics within the bipolar junction transistor. For example, for a double-sided double-base PNP transistor, the control current may flow into an upper N-type region or a lower N-type region, and when so used the upper N-type region and the lower N-type region are considered bases. However, in other cases, such as described in co-pending and commonly assigned U.S. App. 18/483,939 noted above, the control current may flow into an upper P-type region or a lower P-type region, and when so used the upper and lower P-type regions are considered bases.

“Upper” in reference to component (e.g., upper collector-emitter, upper base) shall not be read to imply a location of the recited component with respect to gravity. Upper may be derived from location of the device in an example drawing.

“Lower” in reference to a component (e.g., upper collector-emitter, upper base) shall not be read to imply a location of the recited component with respect to gravity. Lower may be derived from location of the device in an example drawing.

The terms “input” and “output” when used as nouns refer to connections (e.g., electrical, software), and shall not be read as verbs requiring action. For example, a timer circuit may define a clock output. The example timer circuit may create or drive a clock signal on the clock output. In systems implemented directly in hardware (e.g., on a semiconductor substrate), these “inputs” and “outputs” define electrical connections. In systems implemented in software, these “inputs” and “outputs” define parameters read by or written by, respectively, the instructions implementing the function.

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various examples are directed to overcurrent protection for power semiconductor devices that are bidirectional. More particularly, various examples monitor a power semiconductor device carrying a load current, the monitoring by way of a sensing current conducted along a sensing pathway. If the power semiconductor device experiences a desaturation event, the load current is interrupted and the driver circuit arranges itself to avoid shorting the applied voltage through a sensing pathway. For example, a power semiconductor device carrying a forward load current across its terminals may be monitored for desaturation by circulating forward sensing current through a forward sensing pathway that includes the power semiconductor device. If a desaturation event is detected based on the forward sensing current, the forward load current is halted or interrupted, and also a pathway for a reverse sensing current is opened or interrupted to avoid shorting the externally applied voltage through the reverse sensing pathway. Oppositely, the power semiconductor device carrying a reverse load current across its terminals may be monitored for desaturation by circulating a reverse sensing current through a reverse sensing pathway that includes the power semiconductor device. If a desaturation event is detected based on the reverse sensing current, the reverse load current is halted or interrupted, and also a pathway for the forward sensing current is opened or interrupted to avoid shorting the externally applied voltage through the forward sensing pathway. The specification turns to an example system to orient the reader.

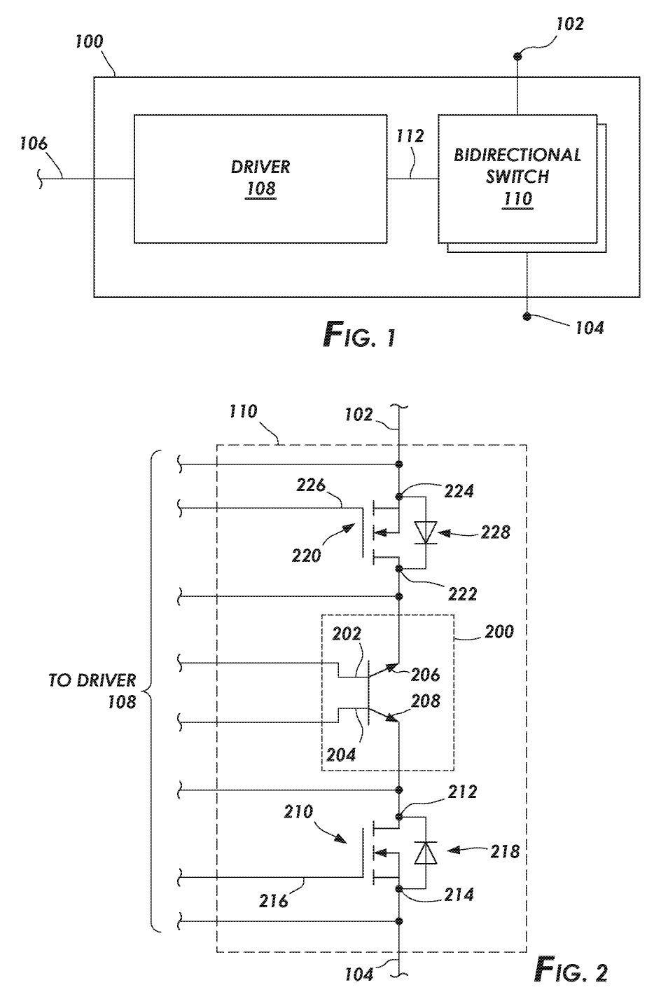

FIG. 1 shows an example switch assembly 100. In particular, the example switch assembly 100 defines an upper terminal 102, a lower terminal 104, and a control input or control terminal 106. Internally, the example switch assembly 100 includes a driver 108 and a power semiconductor device shown as bidirectional switch 110. The driver 108 defines the control terminal 106, and the driver 108 is coupled to the bidirectional switch 110, as shown by connections 112. As discussed in greater detail below, the connections 112, though shown as a single connection, represents a plurality of electrical connections to the bidirectional switch 110 whose conductive state may vary. The driver 108 controls the conductive state of the bidirectional switch 110 by arranging the voltages/currents on the connections 112.

One example of the switch assembly 100 may include a single bidirectional switch 110. Another example of the switch assembly 100 may have two or more bidirectional switches 110, as illustrated in FIG. 1 by the “stacked” arrangement for the bidirectional switch 110. When multiple bidirectional switches 110 are present, the bidirectional switches 110 are electrically connected in parallel to share the main load current (forward or reverse). So as not to unduly complicate the specification, the discussion that follows assumes a single bidirectional switch 110. However, one having ordinary skill, and with the benefit of this disclosure, understands that multiple bidirectional switches may be present depending on the designed current carrying capability of any specific switch assembly 100.

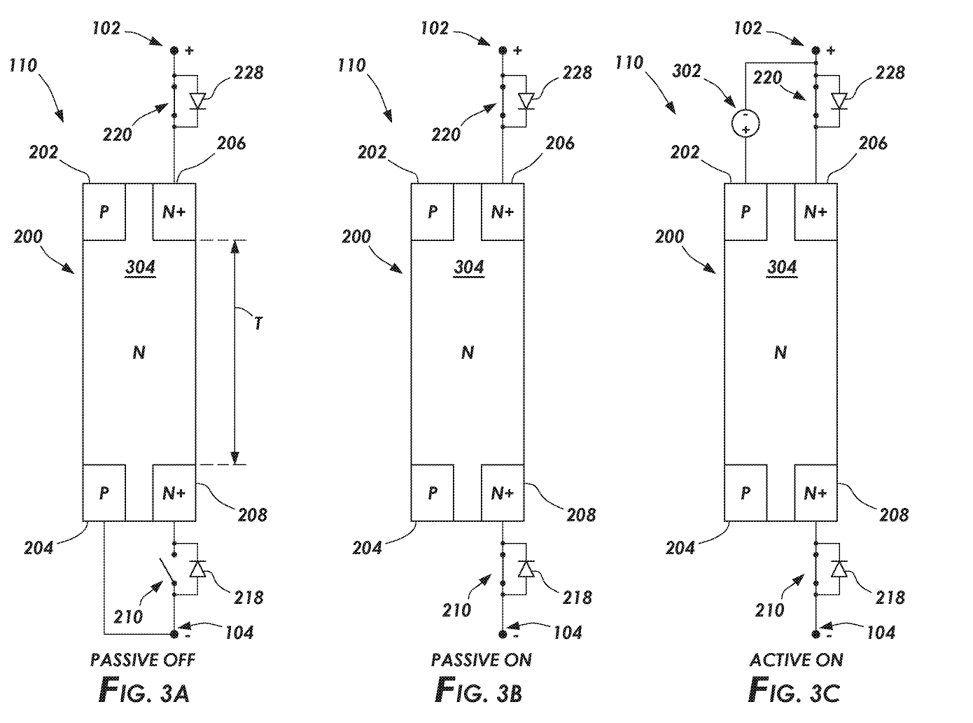

FIG. 2 shows an electrical schematic of an example bidirectional switch 110. In particular, the bidirectional switch 110 comprises a power semiconductor device in the example form of a DSDB-BJT 200. The example DSDB-BJT 200 defines an upper base 202, a lower base 204, an upper collector-emitter 206, and a lower collector-emitter 208. The example bidirectional switch 110 further includes a lower-main or lower cascode FET 210 that defines a drain 212 coupled to the lower collector-emitter 208, a source 214 coupled to the lower terminal 104, a gate 216 coupled to the driver 108, and a body diode 218. Finally, the example bidirectional switch 110 includes an upper-main or upper cascode FET 220 that defines a drain 222 coupled to the upper collector-emitter 206, a source 224 coupled to the upper terminal 102, a gate 226 coupled to the driver 108, and a body diode 228.

The driver 108 is coupled to the bidirectional switch 110 by a plurality of electrical connections. In the example of FIG. 2, the electrical connections to the driver 108 may comprise connections to: the upper terminal 102; the gate 226 of the upper cascode FET 220; the upper collector-emitter 206; the upper base 202; the lower base 204; the lower collector-emitter 208; the gate 216 of the lower cascode FET 210; and the lower terminal 104. In order to describe when each of these connections to the driver 108 may be active, the specification turns to example operation of the DSDB-BJT 200.

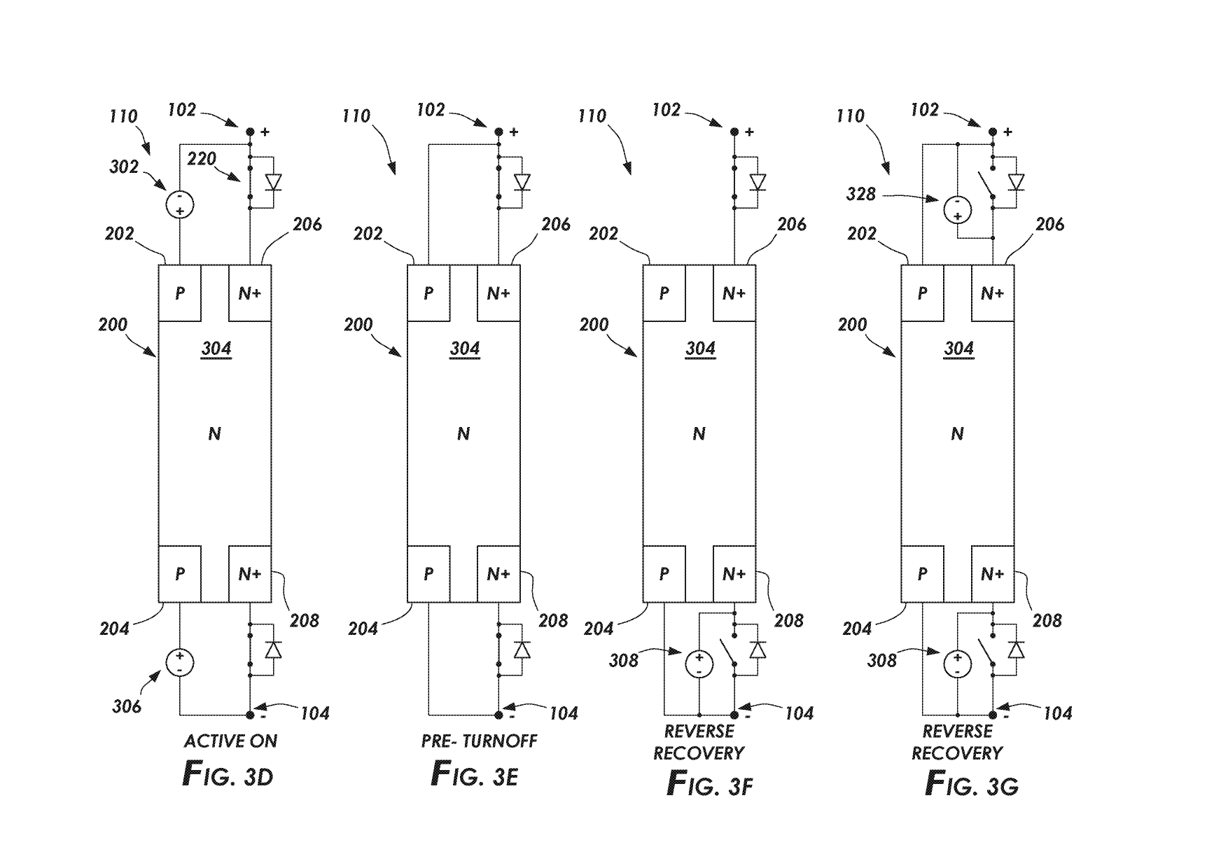

FIGS. 3A-3G show, in shorthand form, the bidirectional switch 110. In particular, visible in each of FIGS. 3A-3G are the upper cascode FET 220 and the lower cascode FET 210, along with their respective body diodes 228 and 218. In order to aid in understanding, the cascode FETs 220 and 210 are shown as single pole, single throw switches. When a cascode FET is conductive, the single pole, single throw switch is shown as closed, and when a cascode FET is non-conductive, the single pole, single throw switch is shown as open. Note that, even though a cascode FET may be non-conductive, the body diode of the cascode FET may be conductive depending on the polarity of the voltage applied to the bidirectional switch 110.

The example DSDB-BJT 200 in each of FIGS. 3A-3G is shown as partial cross-sectional view of a device of PNP construction to illustrate several operational states. In particular, FIGS. 3A-3G show seven example states of the DSDB-BJT 200 arranged for the main load current to be carried across or through the N-type regions, the six states being: passive off (FIG. 3A); passive on (FIG. 3B); active on (FIG. 3C); an alternative active on (FIG. 3D); pre-turn off (FIG. 3E); reverse recovery (FIG. 3F); and an alternative reverse recovery (FIG. 3G). In the examples of FIGS. 3A-3G, the switch assembly 100 is assumed to be forward biased (e.g., having the more positive polarity associated with the upper terminal 102 relative to the lower terminal 104) and thus the switch assembly 100 carries a forward load current. Each example state is addressed in turn.

FIG. 3A shows a passive-off arrangement of the example DSDB-BJT 200. In particular, in the example passive-off arrangement the upper base 202 is electrically floated by the driver 108. The upper collector-emitter 206 is coupled to the upper terminal 102 through the upper cascode FET 220 or its body diode 228. The lower base 204 is coupled to the lower terminal 104 by the driver 108. The lower collector-emitter 208 is electrically floated, such as by the lower cascode FET 210 being open and its body diode 218 being non-conductive because of the applied voltage. In the arrangement of FIG. 3A, no appreciable current flows through the DSDB-BJT 200 because of the blocking performed by the PN junction formed between the lower base 204 and the drift region 304. The state of FIG. 3A is referred as “passive off” because the electrical arrangement can be implemented with purely passive components (e.g., diodes and resistors), and thus the driver 108 need not have operational power to implement the arrangement of FIG. 3A. In the passive-off arrangement, the DSDB-BJT 200 blocks voltage and current, and thus the non-conductive lower cascode FET 210 may experience a relatively small drain-to-source voltage (e.g., 30V or less for 1200V applied across the upper terminal 102 and lower terminal 104).

FIG. 3B shows a passive-on arrangement of the example DSDB-BJT 200. In particular, the upper base 202 is electrically floated by the driver 108. The upper collector-emitter 206 is coupled to the upper terminal 102 through the upper cascode FET 220 or its body diode 228. The lower base 204 is electrically floated by the driver 108. The lower collector-emitter 208 is coupled to the lower terminal 104 through lower cascode FET 210. The voltage drop across the DSDB-BJT 200 in the arrangement of FIG. 3B is based on the substrate resistance (e.g., for a 160 micron thick substrate, about 2 ohms). For an example 30 Amps (A) of main load current, in the passive-on arrangement the DSDB-BJT 200 has a voltage drop of about 60V measured from the upper collector-emitter 206 to the lower collector-emitter 208. The example state of FIG. 3B is referred as “passive on” because the conductive state does not involve injection of charge carriers to lower the forward voltage drop V_{CEON}. An example of injection of charge carriers is shown in the active-on arrangement of FIG. 3C.

FIG. 3C shows an active-on arrangement of the example DSDB-BJT 200, still with the switch assembly 100 forward biased. In particular, the upper base 202 is coupled, through the driver 108, to the upper terminal 102 by way of a source 302 (e.g., voltage source, current source). The upper collector-emitter 206 is coupled to the upper terminal 102 through the upper cascode FET 220 or its body diode 228. The lower base 204 is electrically floated by the driver 108. The lower collector-emitter 208 is coupled to the lower terminal 104 through the lower cascode FET 210. The source 302 provides a positive bias to the upper base 202 relative to the upper collector-emitter 206, and the source 302 may provide any suitable bias voltage (e.g., 0.2 V to 2V). The source 302 injects charge carriers across the PN junction into the bulk substrate or drift region 304, which lowers forward voltage drop V_{CEON}, measured from the upper collector-emitter 206 to the lower collector-emitter 208, to about 0.2V for 30A of main load current. In particular, the arraignment of FIG. 3C injects charge carriers into the upper portion of the drift region 304.

FIG. 3D shows an alternative active-on arrangement of the example DSDB-BJT 200, still with the switch assembly 100 forward biased. In particular, the upper base 202 is coupled, through the driver 108, to the upper terminal 102 by way of the source 302. The upper collector-emitter 206 is coupled to the upper terminal 102 through the upper cascode FET 220 or its body diode 228. The lower base 204 is coupled, through the driver 108, to the lower terminal 104 by way of a source 306 (e.g., voltage source, current source). The lower collector-emitter 208 is coupled to the lower terminal 104 through the lower cascode FET 210. The source 302 provides a positive bias to the upper base 202 relative to the upper collector-emitter 206, and the source 306 provides a positive bias to the lower base 204 relative to the lower collector-emitter 208. The source 302 injects charge carriers across the upper PN junction into the upper portion of the drift region 304, and the source 306 injects charge carriers across the lower PN junction into the lower portion of the drift region 304. The injection of charge carriers lowers forward voltage drop V_{CEON}, measured from the upper collector-emitter 206 to the lower collector-emitter 208, again to about 0.2V for 30A of main load current.

FIG. 3E shows a pre-turnoff arrangement of the example DSDB-BJT 200. In particular, the upper base 202 is coupled, by way of the driver 108, to the upper terminal 102. The upper collector-emitter 206 is coupled to the upper terminal 102 through the upper cascode FET 220 or its body diode 228. The lower base 204 is coupled, by the driver 108, to the lower terminal 104. The lower collector-emitter 208 is coupled to the lower terminal 104 through the lower cascode FET 210. An equivalent arrangement may be to omit the coupling of the upper base 202 to the upper terminal 102. In the pre-turnoff arrangement of FIG. 3E, the example DSDB-BJT 200 presents about a 2-Ohm resistance across the terminals 102 and 104. Thus, for the example 30A main load current, in the pre-turn off arrangement of FIG. 3F the DSDB-BJT 200 presents about a 60V drop measured from the upper collector-emitter 206 to the lower collector-emitter 208.

FIG. 3F shows a reverse recovery arrangement of the example DSDB-BJT 200. In particular, the upper collector-emitter 206 is coupled to the upper terminal 102 through the upper cascode FET 220 or its body diode 228. The lower base 204 is coupled, by the driver 108, to the lower terminal 104. The lower collector-emitter 208 is coupled to the lower terminal 104 by way of a source 308 (e.g., voltage source, current source) of the driver 108. The upper base 202 may be electrically floated by the driver 108. The reverse recovery arrangement of FIG. 3F may be used to shorten the diode reverse recovery time of the PN junction formed between the lower base 204 and the drift region 304 after a period of conduction from the upper collector-emitter 206 to the lower collector-emitter 208, as the PN junction formed by the lower base 204 becomes the primary current/voltage blocking mechanism of the DSDB-BJT 200 when the switch assembly 100 is forward biased. That is, the positive voltage between lower collector-emitter 208 and the lower base 204 pinches off N+/P region formed between the lower collector-emitter 208 and the lower base 204, to reduce reverse recovery current between the upper collector-emitter 206 and the lower base 204. Stated otherwise, in the active-on arrangement of FIGS. 3C or 3D , excess charge carriers are injected in the drift region to lower the forward voltage drop Vceon. However, in the transition from one of the active-on arrangements to the passive-off arrangement of FIG. 3A, the excess charge carriers create undesirable reverse recovery current (I_{RR}) out of the lower base 204, and corresponding increase the reverse recovery time (T_{RR}). Implementing the reverse recovery arrangement of FIG. 3F for a non-zero predetermined period of time reduces the reverse recovery current I_{RR} and thus the reverse recovery time T_{RR}, compared to implementations that do not implement such a reverse recovery step.

FIG. 3G shows an alternative reverse recovery arrangement of the example DSDB-BJT 200. In particular, the upper collector-emitter 206 is coupled to the upper terminal 102 by way of a voltage source 328, and the upper cascode FET 220 is open. The upper base 202 is coupled, by the driver 108, to the upper terminal 102. The lower base 204 is coupled, by the driver 108, to the lower terminal 104. The lower collector-emitter 208 is coupled to the lower terminal 104 by way of a source 308 (e.g., voltage source, current source) of the driver 108. As with the reverse recovery arrangement of FIG. 3F, the alternative reverse recovery arrangement of FIG. 3G may be used to shorten the diode reverse recovery time of the PN junction formed between the lower base 204 and the drift region 304 after a period of conduction from the upper collector-emitter 206 to the lower collector-emitter 208, as the PN junction formed by the lower base 204 becomes the primary current/voltage blocking mechanism of the DSDB-BJT 200 when the switch assembly 100 is forward biased. That is, the positive voltage between lower collector-emitter 208 and the lower base 204 pinches off N+/P region formed between the lower collector-emitter 208 and the lower base 204, to reduce reverse recovery current between the upper collector-emitter 206 and the lower base 204. Similarly, the positive voltage between upper collector-emitter 206 and the upper base 202 helps pinch off N+/P region formed between the lower collector-emitter 208 and the lower base 204. Stated otherwise, in the active-on arrangement of FIGS. 3C or 3D , excess charge carriers are injected in the drift region to lower the forward voltage drop Vceon. However, in the transition from one of the active-on arrangements to the passive-off arrangement of FIG. 3A, the excess charge carriers create undesirable reverse recovery current (I_{RR}) out of the lower base 204, and corresponding increase the reverse recovery time (T_{RR}). Implementing the alternative reverse recovery arrangement of FIG. 3G for a non-zero predetermined period of time reduces the reverse recovery current I_{RR} and thus the reverse recovery time T_{RR}, compared to implementations that do not implement such a reverse recovery step.

With respect to transitions of the switch assembly 100 from non-conductive to conductive, the example DSDB-BJT 200 may be arranged to transition from the passive-off arrangement of FIG. 3A directly to one of the active-on arrangements of FIGS. 3C or 3D without implementing an intermediate arrangement or state. Nevertheless, the passive-on arrangement of FIG. 3B may find use in some circumstances. With the respect to transitions of the switch assembly 100 from conductive to non-conductive, in various examples the DSDB-BJT 200 may be transitioned from one of the active-on arrangements of FIGS. 3C or 3D or to one of the reverse recovery arrangements of FIGS. 3F or 3G , in some cases for between and including 200 and 500 nanoseconds, and in a particular case, about 400 nanoseconds. After implementation of either of the reverse recovery arrangements or states, the DSDB-BJT 200 may then be transitioned to the passive-off state of FIG. 3A.

In some cases, such as when the DSDB-BJT 200 is made non-conductive during a zero current event through the switch assembly 100, the reverse recovery arrangement of FIGS. 3F or 3G may be omitted, and the DSDB-BJT 200 may be transitioned directly to the passive-off arrangement of FIG. 3A. The pre-turnoff arrangement of FIG. 3E may find use in some circumstances.

The examples of FIGS. 3A-3G are for the switch assembly 100 being forward biased and carrying a forward load current. However, the bidirectional switch 110 is a symmetrical device, and now understanding how to control current through the DSDB-BJT 200 when the switch assembly 100 is forward biased, control of current when the switch assembly 100 is reverse biased (i.e., having the more positive polarity associated with the lower terminal 104 relative to the upper terminal 102) and carrying reverse load current directly follows. The “forward” and “reverse” terminology is arbitrarily assigned to aid in the description. Moreover, now understanding various operational states of the PNP configuration with main load current flowing through the N-type regions, one of ordinary skill could derive equivalent arrangements for PNP arrangement with main load current flowing through the P-type regions, and for NPN arrangements.

Referring again to FIGS. 3A. The example DSDB-BJT 200 is shown as monolithic structure. That is, the upper base 202 and upper collector-emitter 206 are associated with or proximate to an upper portion of the drift region 304. Similarly, the lower base 204 and lower collector-emitter 208 are associated with or proximate to a lower portion of the drift region 304. The example drift region 304 is a continuous structure. The example DSDB-BJT 200 may be manufactured by creating the upper base 202 and upper collector-emitter 206 on an upper side of a wafer. The wafer is then flipped and bonded to a handle wafer, and thereafter the lower base 204 and lower collector-emitter 208 are created on the second side of the wafer. Having a continuous drift region 304 may mean that, for positive polarity on the upper terminal 102, charge carrier injection into the upper base 202 (e.g., FIG. 3C) drops the Vceon sufficiently that charge carrier injection from both sides (e.g., FIG. 3D) provides a small additional benefit. Stated otherwise, for devices in which the drift region 304 is continuous, charge carrier injection into the emitter-base (e.g., FIG. 3C) in many cases provides sufficient Vceon reduction, and the further incremental reduction in forward voltage drop attributable to injecting charge carriers in the collector-base (e.g., FIG. 3D) may not justify the additional components and part counts.

However, in other cases the DSDB-BJTs may be created with non-continuous drift regions. For example, DSDB-BJTs may manufactured by creating a plurality of partial components, such as each partial component comprising a base region, a collector-emitter region, and a drift region. The partial components may be diced or singulated, and then a DSDB-BJT may be created by bonding the drift regions of two partial components. Nevertheless, DSDB-BJTs of with non-contiguous drift regions may be operated according to any of FIGS. 3A-3G, though with non-contiguous drift regions the active-on arrangement of FIG. 3D, injecting charge carriers from both sides of the device, may have benefits over the single-sided injection of charge carriers of FIG. 3E.

In the various examples, the injection of charge carriers may take many forms. In particular, the examples of FIGS. 3C and 3D use voltage sources. In the case of injection from both sides of the device (e.g., FIG. 3D), the voltages may be the same. For example, the voltage provided by the source 302 may be the same as the voltage provided by the source 306. In other cases, the voltages may be different. For example, magnitude of the voltage on the collector-side (e.g., source 302) may be greater than the voltage on the emitter side (e.g., source 306).

In other cases, the injection of charge carriers may be by way of current source(s). In the example of FIG. 3C, the source 302 may provide a setpoint current independent of the voltage used to drive the setpoint current. In the example of FIG. 3D injecting charge carriers from both sides, the magnitude of current supplied to the upper base 202 may be the same as the magnitude of the current supplied to the lower base 204. In other cases, the magnitude of the current supplied to the upper base 202 may be different from the magnitude of control current supplied to the lower base 204. The specification and claims embrace all such variations. The specification now turns to a description of the various circuits used to monitor for desaturation of the power semiconductor device in the example form of DSDB-BJT 200.

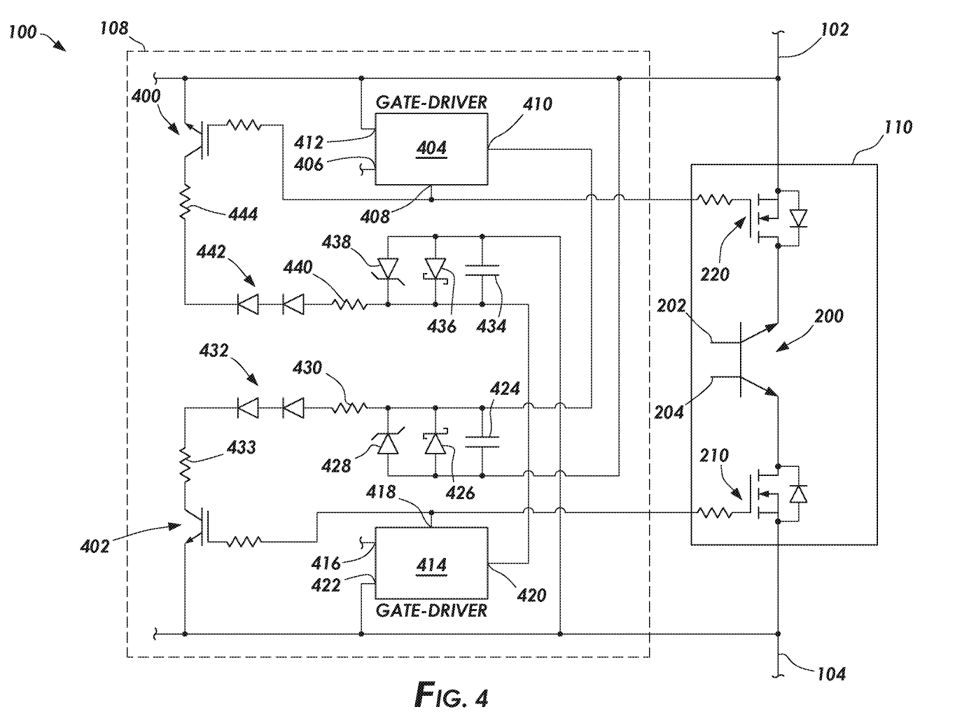

FIG. 4 shows a partial electrical schematic of an example switch assembly 100. In particular, FIG. 4 shows the upper terminal 102, the lower terminal 104, and the bidirectional switch 110. The example bidirectional switch 110 comprises the upper cascode FET 220, the DSDB-BJT 200, and the lower cascode FET 210. FIG. 4 further shows components of the driver 108 associated with monitoring for desaturation of the DSDB-BJT 200. In order to facilitate the discussion regarding monitoring for desaturation events, the driver 108 of FIG. 4 contains only the components involved in the monitoring; however, additional components within the driver 108 will be present, and are shown and discussed below. For example, the various portions of the driver 108 to control the voltages and currents to the upper base 202 and the lower base 204 are omitted in FIG. 4 so as not to unduly complicate the figure.

The example driver 108 comprises: an upper transistor 400 defining a first lead coupled to the upper terminal 102, a second lead, and a base; and a lower transistor 402 defining a first lead coupled to the lower terminal 104, a second lead, and a base. An upper gate-driver 404 defines a drive-in terminal 406, a drive terminal 408, a DSAT terminal 410, and a common or ground terminal 412. The drive-in terminal 406 is coupled to other components of the driver 108 discussed more below. The drive terminal 408 is coupled to both the gate of the upper cascode FET 220 and the base of the upper transistor 400. The DSAT terminal 410 is coupled to the second lead of the lower transistor 402. The upper gate-driver 404 is configured to, responsive to assertion of drive-in terminal 406, assert the drive terminal 408, and drive a reverse DSAT current or reverse sensing current. The reverse sensing current flows through the lower transistor 402, the DSDB-BJT 200, and back to the upper gate-driver 404 by way of the ground terminal 412. The upper gate-driver 404 is further designed and constructed to, responsive to an overcurrent condition detected using the reverse sensing current, de-assert its drive terminal 408 to make the upper cascode FET 220 and the upper transistor 400 non-conductive. A more detailed explanation is provided after introduction of the remaining components of FIG. 4.

The example driver 108 further comprises a lower gate-driver 414 that defines a drive-in terminal 416, a drive terminal 418, a DSAT terminal 420, and a common or ground terminal 422. The drive-in terminal 416 is coupled to other components of the driver 108 discussed more below. The drive terminal 418 is coupled to both the gate of the lower cascode FET 210 and the base of the lower transistor 402. The DSAT terminal 420 is coupled to the second lead of the upper transistor 400. The lower gate-driver 414 is designed and constructed to, responsive to assertion of its drive-in terminal 416, assert the drive terminal 418, and drive a forward DSAT current or forward sensing current. The forward sensing current flows through the upper transistor 400, the DSDB-BJT 200, and back to the lower gate-driver 414 by way of the ground terminal 422. The lower gate-driver 414 is further designed and constructed to, responsive to an overcurrent condition detected using the forward sensing current, de-assert the drive terminal 418 to make the lower cascode FET 210 and the lower transistor 402 non-conductive.

In some cases, the upper transistor 400 and lower transistor 402 are each an integrated gate bipolar junction transistor (IGBT), as shown, though any suitable transistor may be used, and the transistor type need not be uniform. For reasons that will become clearer based on the discussion that follows, the voltage blocking capability of each of the upper and lower transistors 400 and 402 should be about the same as the voltage blocking capability of the switch assembly 100 itself. For example, if the switch assembly is designed for 1200V service, then the upper and lower transistors should be rated for at least 1200V service.

Any suitable gate driver circuit may be used to implement the upper gate-driver 404 and the lower gate-driver 414. For example, a High Current IGBT Gate Driver part number NCV5705, available from onsemi of Phoenix, AZ, may be used. The upper gate-driver 404 may be used to simultaneously drive the gate of the upper transistor 400 and the gate of the upper cascode FET 220. Similarly, the lower gate-driver 414 may be used to simultaneously drive the gate of the lower transistor 402 and the gate of lower cascode FET 210.

Still referring to FIG. 4, the DSAT terminal 420 of the lower gate-driver 414 is coupled to the second lead of the upper transistor 400 through a network of components. In particular, the example network of components comprises a capacitor 434, a Schottky diode 436, a Zener diode 438, a resistor 440, a set of diodes 442, and a resistor 444. The resistor 440 and capacitor 434 form an RC filter. The Schottky diode 436 is provided for reverse polarity shorting, and the Zener diode 438 protects against overvoltage conditions. The set of diodes 432 act to block current flow in certain situations, discussed more below. The lower gate-driver 414 drives a forward sensing current during periods of time when the switch assembly 100 is carrying forward load current. Thus, the electrical pathway from the lower gate-driver 414 through the upper transistor 400 represents a forward DSAT pathway or forward sensing pathway.

Similarly, the DSAT terminal 410 of the upper gate-driver 404 is coupled to the second lead of the lower transistor 402 through a network of components. In particular, the example network of components comprises a capacitor 424, a Schottky diode 426, a Zener diode 428, a resistor 430, and a set of diodes 432, and a resistor 433. The resistor 430 and capacitor 424 form an RC filter. The Schottky diode 426 is provided for reverse polarity shorting, and the Zener diode 428 protects against overvoltage conditions. The set of diodes 432 act to block current flow in certain situations, discussed more below. The upper gate-driver 404 drives a reverse DSAT current or reverse sensing current during periods of time when the switch assembly 100 is carrying reverse load current. Thus, the electrical pathway from the upper gate-driver 404 through the lower transistor 402 represents a reverse DSAT pathway or reverse sensing pathway. The specification now turns to a series of figures to visually represent how the sensing currents flow in relation to the direction of the load current flow.

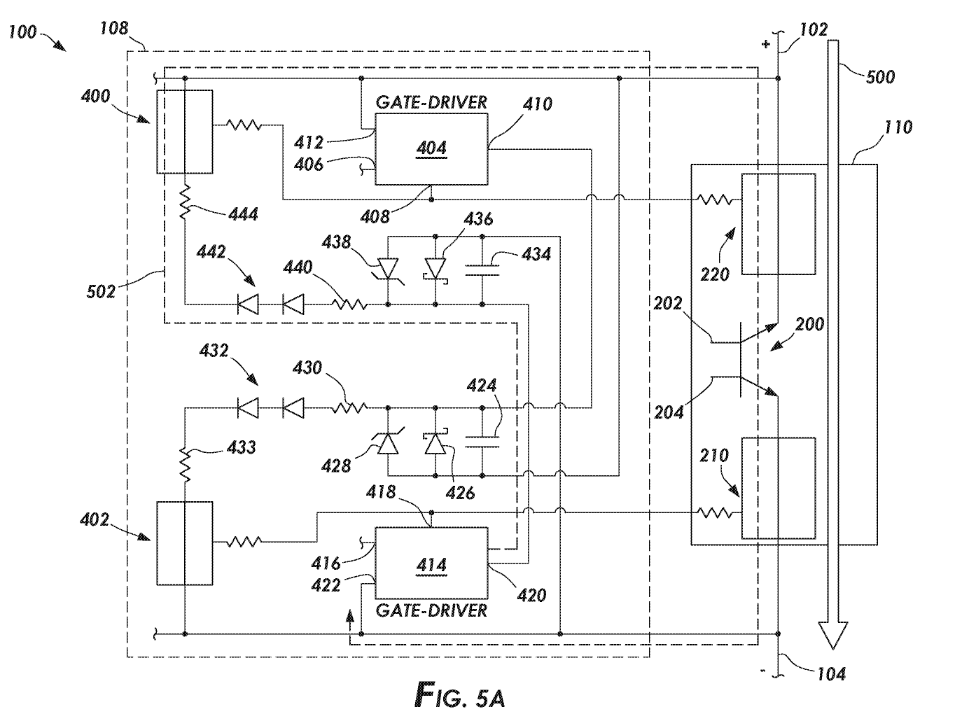

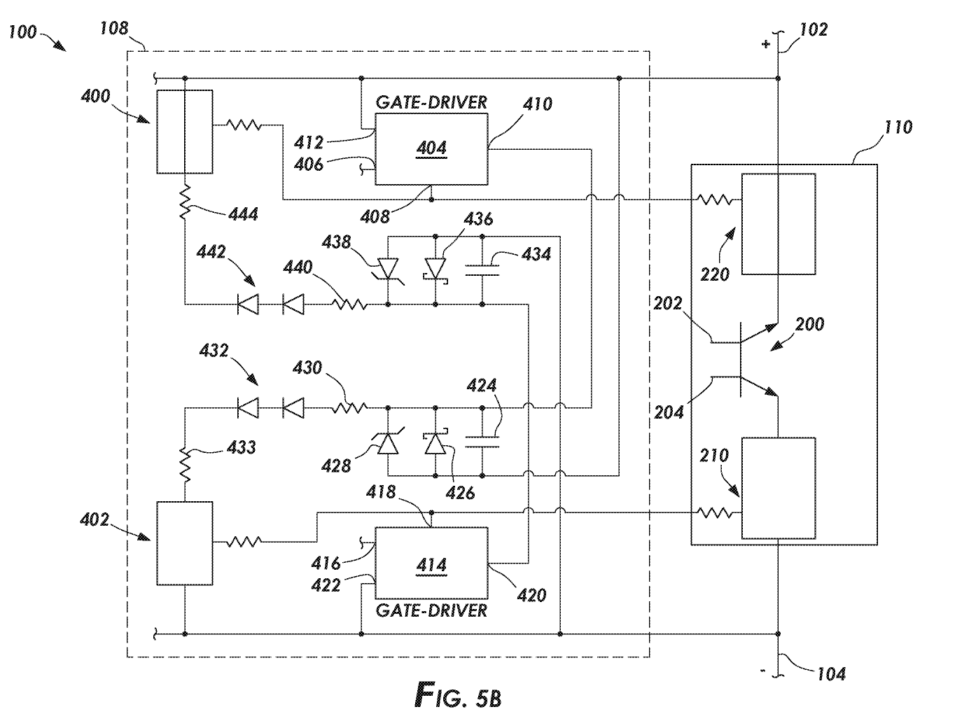

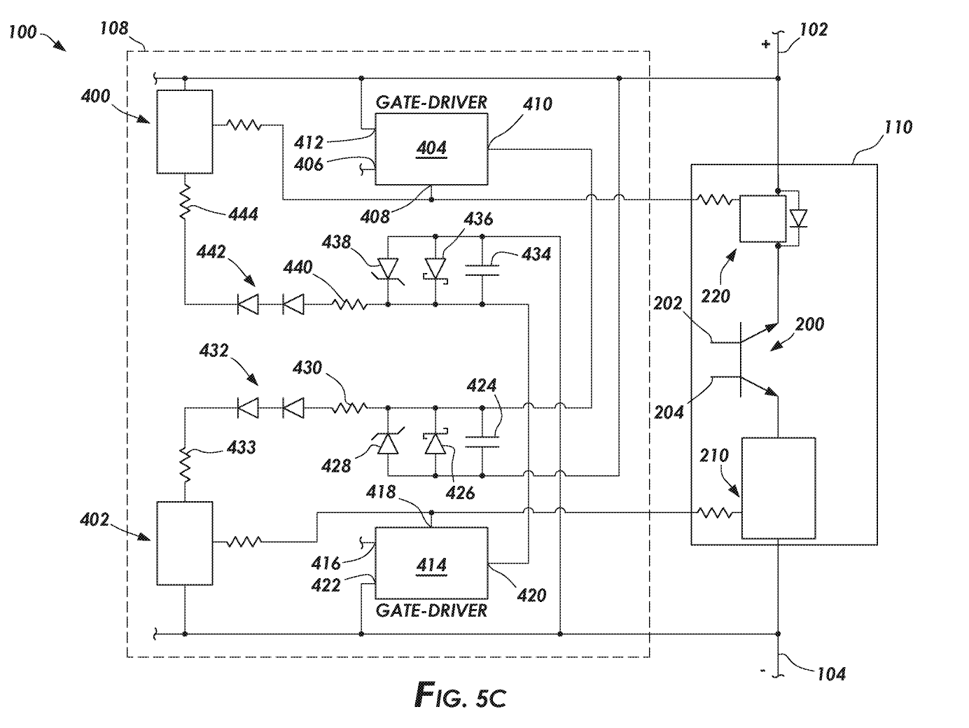

FIG. 5A shows a partial electrical schematic of an example switch assembly 100. In particular, FIG. 5A shows a situation with a forward bias applied to the switch assembly 100, as shown by the “+” symbol by the upper terminal 102 and a “—“ symbol by the lower terminal 104. Further consider that a forward load current is flowing as shown by arrow 500. In the example situation, the upper and lower transistors 400 and 402 are conductive, and similarly the upper and lower cascode FETs 220 and 210 are conductive, and thus those devices are shown as electrical short circuits. A forward sensing current (shown in dashed lines as a current path 502) is driven from the DSAT terminal 420 of the lower gate-driver 414, along the pathway including resistor 440, set of diodes 442, and upper transistors 400. The forward sensing current flows through the DSDB-BJT 200, and returns to the lower gate-driver 414 by way of the ground terminal 422. The forward sensing current may have a relatively small amplitude, on the order of milli-Amps, while the forward load current may be 30 to 60A. However, if the voltage used to drive the forward load current reaches or exceeds a predetermined threshold, a desaturation event is occurring within the DSDB-BJT 200, and thus the lower gate-driver 414 takes action.

In particular, responsive to the voltage used to drive the forward sensing current reaching or exceeding a predetermined threshold, the lower gate-driver 414 interrupts the forward current by de-asserting the drive terminal 418, in spite of the fact the drive-in terminal 416 is still asserted by other components of the driver 108. De-asserting the drive terminal 418 thus makes the lower transistor 402 and the lower cascode FET 210 non-conductive.

FIG. 5B shows a partial electrical schematic of an example switch assembly 100. In particular, FIG. 5B the situation after a desaturation event has been detected, but before the remaining portions of the driver 108 have had a chance to react. Lower transistor 402 and lower cascode FET 210 are now non-conductive, and those devices are illustrated as open circuits. In this situation, the forward load current has ceased based on the opening of the lower cascode FET 210. The positive voltage at the upper terminal 104 extends through the upper transistor 400, but is blocked from reaching the lower gate-driver 414 by way of the set of diodes 442. In this situation, the ground terminal 412 of the upper gate-driver 404 is coupled to the positive voltage at the upper terminal. It follows that, even if the upper gate-driver 404 is internally “grounding” its DSAT terminal 410, the positive voltage at the upper terminal 102 is still being applied to components downstream of the DSAT terminal 410, that is, along the forward sensing pathway. However, the lower transistor 402, being non-conductive or open, prevents a short of the positive voltage at the upper terminal 102 from reaching the lower terminal 104 through the upper gate-driver 404.

A certain time later, the controller (discussed more below) of the driver 108 senses the desaturation event, and the controller de-asserts the drive-in terminal 406 of the upper gate-driver 404 and the drive-in terminal 416 of the lower gate-driver 414. While de-assertion of the drive-in terminal 416 of the lower gate-driver 414 has no effect, de-assertion of the drive-in terminal 406 of the upper gate-driver 404 results in de-assertion of the drive terminal 408, thus making the upper transistor 400 and the upper cascode FET 220 non-conductive.

FIG. 5C shows a partial electrical schematic of an example switch assembly 100. In particular, FIG. 5C shows the situation after a desaturation event, and the after the driver 108 has de-asserted the drive-in terminals 406 and 416 of the upper and lower gate-drivers 404 and 414, respectively. In the example situation with forward bias, both the upper and lower transistors 400 and 402 are non-conductive, and both the upper and lower cascode FETs 220 and 210 are non-conductive (though the body diode 228 of the upper cascode FET 220 may still be conductive). The DSDB-BJT 200 may also be non-conductive, or in the process of becoming non-conductive. Lower transistor 402 blocks shorting through the upper gate-driver 404.

The example switch assembly of FIGS. 5A-5C is a bidirectional device. Thus, now understanding how the forward sensing current moves along the forward sensing pathway during forward bias, and how the how lower transistor 402 blocks shorting along the reverse sensing pathway, operation of the device when the switch assembly 100 is reverse biased and reverse load current follows. In the reverse biased situation, after the load current is interrupted because of a desaturation event, the upper transistor 400 blocks shorting through the lower gate-driver 414 along the forward sensing pathway.

The forward sensing current and reverse sensing current are driven by the lower gate-driver 414 and upper gate-driver 404, respectively. As alluded to above, each sensing current is relatively small current, in some cases on the order of micro-amps or milli-amps. Each sensing current is driven from within the gate-driver, such as form a constant-current source. That is, devices within the gate-driver control apply a variable voltage to achieve the setpoint sense current. When a desaturation event occurs, the variable voltage rises in an attempt maintain the setpoint value for the sense current. When the variable voltage rises above a predetermined threshold, the gate-driver senses the situation as indicating the presence of a desaturation event.

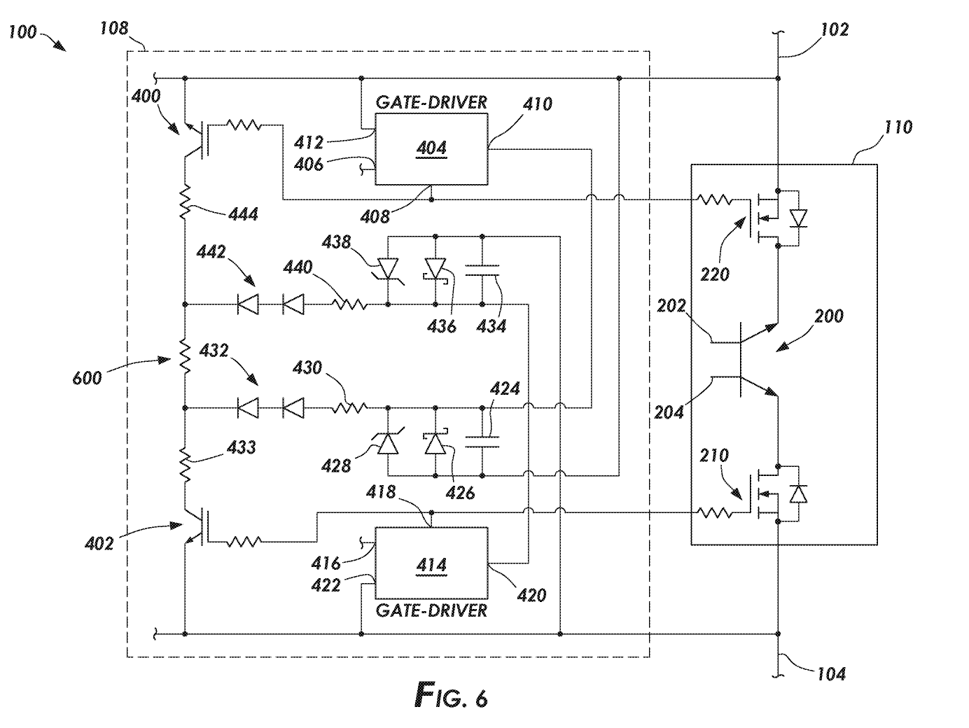

FIG. 6 shows a partial electrical schematic of an example switch assembly 100. In particular, FIG. 6 shows the partial switch assembly 100 of FIGS. 5A-5C, along with additional components that enable selecting or tuning the point at which the gate-drivers 404 and 414 trigger based on desaturation events. In particular, resistor 600 is coupled between the anode of the set of diodes 432 and the anode of the set of diodes 442. The resistance of the resistor 600 is selected to tune or control the trip point for the forward and reverse sense currents in the event the gate-drivers 404 and 414 are not otherwise tunable. Consider again the forward sense current emanating from the DSAT terminal 420 of the lower gate-driver 414. The addition of resistor 600 creates a parallel electrical pathway for a portion of the forward sense current – some of the forward sense current flows through the lower transistor 402 and through the DSDB-BJT 200, and another portion flows through the resistor 600 and the upper transistor 400. Thus, by selecting resistance of the resistor 600, the circuit designer may control or select the extent of desaturation of the DSDB-BJT 200 at which load current is interrupted. Stated otherwise, in some cases the predetermined drive voltage at which a gate-driver de-asserts is drive terminal is controlled by the manufacturer of the gate-driver. By including resistor 600, the designer of the switch assembly 100 may effectively control the point at which the gate-drivers sense the presence of the desaturation event.

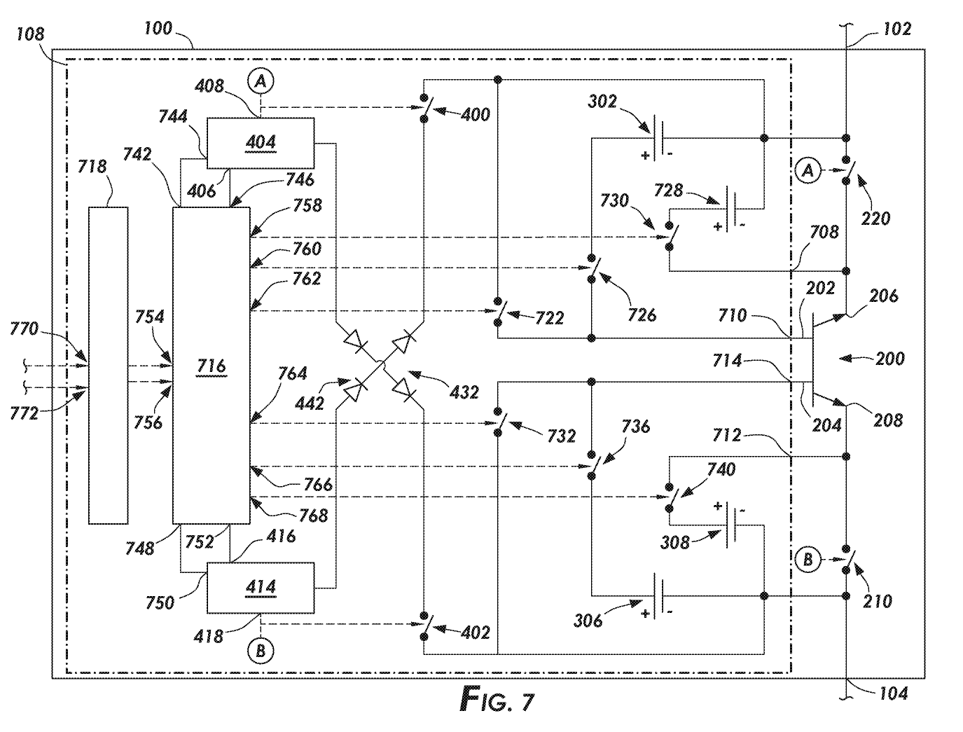

FIG. 7 shows a partial block diagram, partial electrical schematic, of an example switch assembly 100. In particular, visible in FIG. 7 are the upper terminal 102, the driver 108, the DSDB-BJT 200, and the lower terminal 104. The example driver 108 defines an upper collector-emitter terminal 708 coupled to the upper collector-emitter 206, an upper conduction terminal 710 coupled to the upper base 202, a lower collector-emitter terminal 712 coupled to the lower collector-emitter 208, and a lower-conduction terminal 714 coupled to the lower base 204. In order to reduce complexity of the drawing, and to facilitate understanding, in FIG. 7 transistors (e.g., transistors 400 and 402) and FETs (e.g., cascode FETs 210 and 220) are shown as electrically-controlled switches, and in particular single-pole, single-throw switches with a control input. Hereafter, the electrically-controlled switches referred to as just switches; however, it will be understood that any suitable electrically-controlled switches may be used at the discretion of the circuit designer.

As before, the upper cascode FET 220 is coupled between the upper terminal 102 and the upper collector-emitter 206. When the upper cascode FET 220 is made conductive, such as by assertion of its control input, the upper terminal 102 is coupled to the upper collector-emitter 206. Similarly, the lower cascode FET 210 is coupled between the lower collector-emitter 208 and the lower terminal 104. When the lower cascode 210 is conductive, such as by assertion of its control input, the lower terminal 104 is coupled to the lower collector-emitter 208. In the example of FIG. 7, the cascode FETs may be co-packaged with the power semiconductor device in the example form of the DSDB-BJT 200; however, in other cases the DSDB-BJT 200 may be individually packaged, and thus the cascode FETs may be placed within and be members of the driver 108.

The example driver 108 comprises the upper gate-driver 404, the upper transistor 400, the lower gate-driver 414, and the lower transistor 402. Also visible in FIG. 7 is the set of diodes 442 of the forward sense pathway, and the set of diodes 432 of the reverse sense pathway. The various additional electrical components of the forward and reverse sense pathways (e.g., the RC filter and protection diodes) are omitted so as not to unduly complicate the figure. The upper gate-driver 404 is coupled, by way of its drive terminal 408, to the gate of the upper transistor 400, as well as the gate of the upper cascode FET 220 (as shown by bubble “A”). The lower gate-driver 414 is coupled, by way of its drive terminal 418, to the gate of the lower transistor 402, as well as the gate of the lower cascode FET 210 (as shown by bubble “B”).

The example driver 108 further comprises a controller 716 and an electrical isolator 718. In order to place the DSDB-BJT 200 in the various conduction and non-conduction modes (e.g., FIGS. 3A-3G), the example driver 108 includes several electrically-controlled switches and sources of charge carrier. In particular, the example driver 108 comprises a switch 722 that has its first lead coupled to the upper terminal 102, a second lead coupled to the upper base 202, and a control input coupled to the controller 716. Thus, when the switch 722 is made conductive by assertion of its control input, the upper terminal is coupled to the upper base 202.

The driver 108 further comprises the source 302 illustratively shown as a battery. The source 302 has a negative lead coupled to the upper terminal 102. Another switch 726 has a first lead coupled to the positive terminal of the source 302, a second lead coupled to the upper base 202, and a control input coupled to the controller 716. Thus, when the switch 726 is conductive, the source 302 is coupled between the upper terminal 102 and the upper base 202.

The driver 108 further comprises a source 728 illustratively shown as a battery. The source 728 has a negative lead coupled to the upper terminal 102. Another switch 730 has a first lead coupled to the positive terminal of the source 728, a second lead coupled to the upper collector-emitter 206, and a control input coupled to the controller 716. Thus, when the switches 722 and 730 are conductive, the source 728 is coupled between the upper collector-emitter 206 and the upper base 202 (e.g., reverse recovery for an externally applied voltage more positive at the lower terminal 104, or the alternative reverse recovery for the externally applied voltage more positive on the upper terminal 102).

Turning now to lower side of the DSDB-BJT 200, the example driver 108 further comprises a switch 732 that has a first lead coupled to the lower terminal 104, a second lead coupled to the lower base 204, and a control input coupled to the controller 716. Thus, when the switch 732 is made conductive by assertion of its control input, the lower base 204 is coupled to the lower terminal 104.

The driver 108 further comprises the source 306 illustratively shown as a battery. The source 306 has a negative lead coupled to the lower terminal 104. Another switch 736 has a first lead coupled to the positive terminal of the source 306, a second lead coupled to the lower base 204, and a control input coupled to the controller 716. Thus, when the switch 736 is conductive, the source 306 is coupled between the lower terminal 104 and the lower base 204.

The example driver 108 further comprises the source 308 illustratively shown as a battery. The source 308 has a negative lead coupled to the lower terminal 104. Another switch 740 has a first lead coupled to the positive terminal of the source 308, a second lead coupled to the lower collector-emitter 208, and a control input coupled to the controller 716. Thus, when the switches 732 and 740 are conductive, the source 308 is coupled between the lower base 204 and the lower collector-emitter 208 (e.g., reverse recovery shown in FIG. 3F).

The controller 716 defines an overcurrent input 742 coupled to an overcurrent terminal 744 of the upper gate-driver 404. When the upper gate-driver 404 senses an overcurrent event, the gate-driver assets the overcurrent terminal 744 to pass the information along to the controller 716. The controller 716 defines a drive output 746 coupled to the drive-in terminal 406 of upper gate-driver 404. Thus, the controller 716 asserts the drive output 746 to command making the upper cascode FET 220 conductive. With respect to sensing desaturation events, in other cases the controller 716 may be coupled to and directly sense a signal driven on the drive terminal 408 as an indication of an overcurrent event. That is, if the drive output 746 of the controller 716 is asserted, but the drive terminal 408 goes de-asserted, such may be indicative of a desaturation event.

Similarly, the controller 716 defines an overcurrent input 748 coupled to an overcurrent terminal 750 of the lower gate-driver 414. When the lower gate-driver 414 senses an overcurrent event, the gate-driver assets the overcurrent terminal 750 to pass the information along to the controller 716. The controller 716 defines a drive output 752 coupled to the drive-in terminal 416 of the lower gate-driver 414. Thus, the controller 716 asserts the drive output 752 to command making the lower cascode FET 210 conductive. With respect to sensing desaturation events, in other cases the controller 716 may be coupled to and directly sense a signal driven on the drive terminal 418 as an indication of an overcurrent event. That is, if the drive output 746 of the controller 716 is asserted, but the drive terminal 418 goes de-asserted, such may be indicative of a desaturation even.

Still referring to FIG. 7, the example controller 716 further defines control inputs 754 and 756. When the control input 754 is asserted, the controller 716 is designed and constructed to arrange the DSDB-BJT 200 for conduction from the upper terminal 102 to the lower terminal 104. Oppositely, when the control input 754 is de-asserted, the controller 716 is designed and constructed to arrange the DSDB-BJT 200 to block current flow from the upper terminal 102 to the lower terminal 104. Similarly, when the control input 756 is asserted, the controller 716 is designed and constructed to arrange the DSDB-BJT 200 for conduction from the lower terminal 104 to the upper terminal 102. Oppositely, when the control input 756 is de-asserted, the controller 716 is designed and constructed to arrange the DSDB-BJT 200 to block current flow from the lower terminal 104 to the upper terminal 102. When the control inputs 754 and 756 are both asserted, the controller 716 arranges the DSDB-BJT 200 for current flow in both directions (e.g., AC breaker service), and when the control inputs 754 and 756 are both de-asserted, the controller 716 arranges the DSDB-BJT 200 to block current flow in both directions.

The example controller 716 further defines control outputs 758, 760, 762, 764, 766, and 768. The control output 758 is coupled to the control input for switch 730. The control output 760 is coupled to the control input for switch 726. The control output 762 is coupled to the control input for switch 722. The control output 764 is coupled to the control input for switch 732. The control output 766 is coupled to the control input for switch 736. And the control output 768 is coupled to the control input for switch 740. Thus, by selective assertion of the control outputs 758 through 768, the controller 716 is designed and constructed to arrange the DSDB-BJT 200 for any of the conduction or non-conduction modes described with respect to FIGS. 3A-3G.

Transitioning the DSDB-BJT 200 from being non-conductive, to conductive, and then back to non-conductive may be a multistep process. Moreover, the controller 716 may take situation specific action when either of the upper or lower gate-drivers 404 or 414 assert their respective overcurrent terminals 744 and 750. To implement the multistep process or situation-specific action, the controller 716 may be individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations, configured to read the control inputs 754 and 756, and read and drive control outputs to implement the mode transitions of the DSDB-BJT 200. Note that each of the control outputs 758 through 768 may be associated with a gate-driver to provide voltage and current to drive the electrically-controlled switches; however, those additional gate drivers are not included so as not to unduly complicate the figure, or may be included as part of the controller 716.

In example systems, the switch assembly 100 is electrically floated. In order to receive the control inputs 754 and 756 in the electrical domain of the switch assembly 100, the example driver 108 implements the electrical isolator 718. The example electrical isolator 718 may take any suitable form, such as optocouplers or capacitive isolation devices. Regardless of the precise nature of the electrical isolator 718, external control signals (e.g., Boolean signals) may be coupled to control inputs 770 and 772 of the electrical isolator 718. Either of the control inputs 770 or 772 may be the control terminal 106 illustratively presented in FIG. 1. The electrical isolator 718, in turn, passes the control signals through to the electrical domain of the switch assembly 100. In the example, the external control signals are passed through to become the control inputs 754 and 756 of the controller 716.

Consider, as an example, a situation in which the applied voltage has the positive polarity on the upper terminal 102. Further consider that the control input 770 applied to the electrical isolator 718 is de-asserted, and thus a control signal applied to the control input 754 of the controller 716 is de-asserted. Based on the de-asserted state of the control input 754, the controller 716 is designed and constructed to place the DSDB-BJT 200 in the non-conductive arrangement taking into account the applied polarity. Thus, in the example arrangement the upper cascode FET 220 is conductive, the lower cascode FET 210 is non-conductive, and the switch 732 is conductive (passive off). In some examples, the upper cascode FET 220 is made conductive by the controller 716 asserting the drive output 746. However, in other cases, the body diode of the upper cascode FET 220, and thus the conductivity of upper cascode FET 220, may be based, initially at least, on the applied voltage forward biasing the body diode of the FET. A similar arrangement and/or operation may exist for the lower cascode FET 210 when arranged for blocking current for the opposite polarity.

Still considering the example arrangement of the positive polarity at the upper terminal 102, now consider that the control signal applied to the control input 770 of the electrical isolator 718 is asserted, and thus the control signal applied to the control input 754 of the controller 716 is asserted. Based on the assertion, the controller 716 may be designed and constructed to place the DSDB-BJT 200 directly into the active-on arrangement (FIG. 3C). To that end, the controller 716 may assert the drive output 746 (if not already asserted) to make the upper cascode FET 220 conductive, assert the control output 760 to make the switch 726 conductive, assert the drive output 752 to make the lower cascode FET 210 conductive, and de-assert or leave de-asserted the remaining control outputs. In some cases, the controller 716 may be designed and constructed to implement the alternative active-on arrangement of FIG. 3D, and thus controller 716 may also assert the control output 766 to couple the source 306 between the lower terminal 104 and the lower base 204.

Optionally, again with the positive polarity at the upper terminal 102, the controller 716 may be designed and constructed to take the DSDB-BJT 200 through an intermediate conductive arrangement before arriving at the active-on arrangement. For example, the controller 716 may momentarily place the DSDB-BJT 200 in the passive-on arrangement (FIG. 3B). When used, the passive-on arrangement may last a predetermined period (e.g., from about 0.1 μs to 5 μs).

In the active-on arrangement, and for the positive polarity at the upper terminal 102, the source 302 injects charge carriers into the upper base 202. Injecting charge carriers into the upper base 202 increases the number of charge carriers in the drift region of the DSDB-BJT 200, which lowers the V_{CEON} measured across the collector-emitters 206 and 208. In one example, the source 302 injecting charge carriers may lower the V_{CEON} to about 0.2V for about 30A to 100A of current flow through the collector-emitters 206 and 208. The source 302 may take any suitable voltage between and including 0.5V and 5.0V, in some cases between 0.6V and 1.5V.

Still referring to FIG. 7, and still considering the positive polarity on the upper terminal 102. Further consider that the control input 770 applied to the electrical isolator 718 transitions from asserted to de-asserted, and thus a control signal applied to the control input 754 of the controller 716 transitions from asserted to de-asserted. Based on the transition, the controller 716 may be designed and constructed to place the DSDB-BJT 200 into the reverse recovery arrangement (FIG. 3F). To that end, the controller 716 de-asserts the drive output 752 to make the lower cascode FET 210 non-conductive to interrupt the main load current through the DSDB-BJT 200, de-asserts the control output 760 to make the switch 726 non-conductive, asserts the control output 764 to make the switch 732 conductive to couple the lower base 204 to the lower terminal 104, and asserts the control output 768 to make the switch 740 conductive to couple the source 308 between the lower base 204 and the lower collector-emitter 208. As previously mentioned, the reverse recovery arrangement may be implemented for a predetermined period of time, in some cases about 400 nanoseconds. Thereafter, the controller 716 may transition the DSDB-BJT 200 to the passive-off arrange of FIG. 3A.

The example operation discussed with respect to FIG. 7 was with the positive polarity on the upper terminal 102. Again, however, the example DSDB-BJT 200 and the related driver 108 are symmetrical, and now understanding how to arrange the DSDB-BJT 200 into the various conductive and non-conductive states, control of current flow in the opposite direction directly follows.

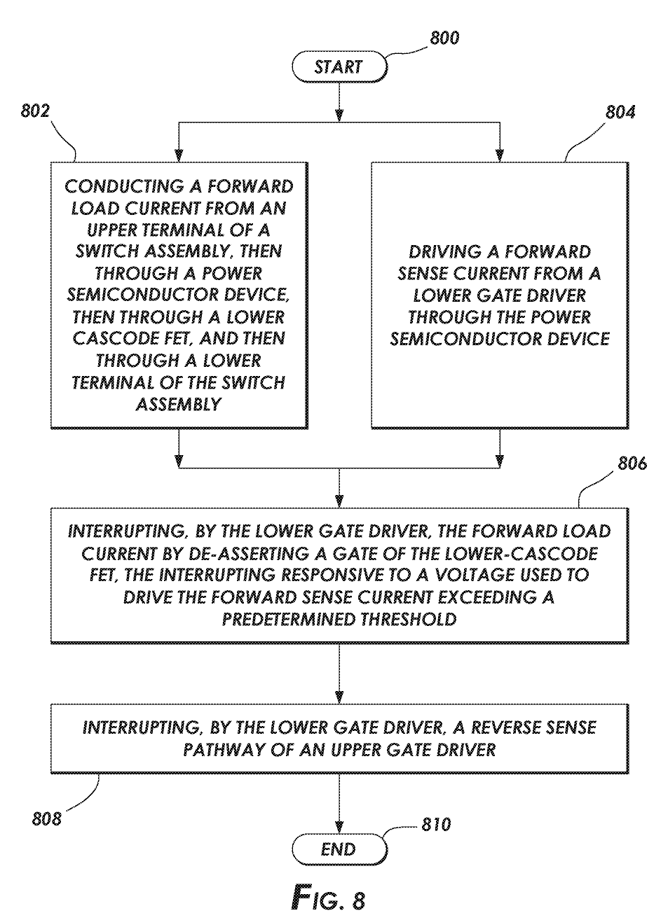

FIG. 8 shows and example method. In particular, the method starts (block 800) and comprises: conducting a forward load current from an upper terminal of a switch assembly, then through a power semiconductor device, then through a lower cascode FET, and then through a lower terminal of the switch assembly (block 802); and simultaneously driving a forward sense current from a lower gate driver through the power semiconductor device (block 804); and thereafter interrupting, by the lower gate driver, the forward load current by de-asserting a gate of the lower-cascode FET, the interrupting responsive to a voltage used to drive the forward sense current exceeding a predetermined threshold (block 806); and interrupting, by the lower gate driver, a reverse sense pathway of an upper gate driver (block 808). Thereafter, the method ends (block 810).

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The above discussion is meant to be illustrative of the principles and various embodiments of the present invention. Numerous variations and modifications will become apparent to those skilled in the art once the above disclosure is fully appreciated. For example, the various drawings show the forward sensing current flowing through the upper cascode FET 220, then through the DSDB-BJT 200; however, in alternative arrangements the forward sensing current may be injected by way of the upper collector-emitter terminal 708, thus bypassing the upper cascode FET 220. Similarly, the various drawings show the reverse sensing current flowing through the lower cascode FET 210, then through the DSDB-BJT 200; however, in alternative arrangements the reverse sensing current may be injected by way of the lower collector-emitter terminal 712, thus bypassing the lower cascode FET 210. It is intended that the following claims be interpreted to embrace all such variations and modifications.

What is claimed is:

1. A method of operating a switch assembly, the method comprising:
conducting a forward load current from an upper terminal of the switch assembly, then through a power semiconductor device, then through a lower cascode FET, and then through a lower terminal of the switch assembly; and simultaneously
driving a forward sense current from a lower gate driver through the power semiconductor device; and thereafter
interrupting, by the lower gate driver, the forward load current by de-asserting a gate of the lower cascode FET, the interrupting responsive to a voltage used to drive the forward sense current exceeding a predetermined threshold; and
interrupting, by the lower gate driver, a reverse sense pathway of an upper gate driver.

2. The method of claim 1 wherein driving the forward sense current comprises driving the forward sense current from the lower gate driver through an upper transistor, then through the power semiconductor device, then through the lower cascode FET, and then back to the lower gate driver.

3. The method of claim 2 further comprising blocking the forward sense current using the upper transistor.

4. The method of claim 2 wherein the upper transistor is at least one selected from a group comprising: a junction transistor; an integrated gate bipolar junction transistor.

5. The method of claim 1 wherein interrupting the forward load current and interrupting the reverse sense pathway is based on the lower gate driver de-asserting a single gate terminal.

6. The method of claim 1 wherein the power semiconductor device is a double-sided double-base bipolar junction transistor.

7. The method of claim 6 wherein conducting the forward load current further comprises driving charge carriers into a drift region of the bipolar junction transistor.

8. The method of claim 7 wherein driving charge carriers further comprises injecting charge carriers through an upper base or a lower base of the bipolar junction transistor.

9. The method of claim 1 further comprising:
conducting a reverse load current from the lower terminal of the switch assembly, then through the lower cascode FET, then through the power semiconductor device, then through an upper cascode FET, and then through the upper terminal of the switch assembly; and simultaneously
driving a reverse sense current from an upper gate-driver through the power semiconductor device; and thereafter
interrupting, by the upper gate driver, the reverse load current by de-asserting a gate of the upper cascode FET, the interrupting the reverse load current responsive to a voltage used to drive the reverse sense current exceeding a predetermined threshold; and
interrupting, by the upper gate driver, a forward sense pathway of the upper gate driver.

10. The method of claim 9 wherein driving the reverse sense current comprises driving the reverse sense current from the upper gate driver, then through a lower transistor, then through the lower cascode FET, then through power semiconductor device, then through the upper cascode FET, and then back to the upper gate driver.

11. The method of claim 10 further comprising blocking the reverse sense current using the lower transistor.

12. The method of claim 9 wherein interrupting the reverse load current and interrupting the forward sense pathway is based on the upper gate-driver de-asserting a single gate terminal.

13. A switch assembly comprising:
an upper terminal, a lower terminal, and a control input;
an upper cascode FET defining a first lead coupled to the upper terminal, a second lead, and a gate;
a lower cascode FET defining a first lead coupled to the lower terminal, a second lead, and a gate;
a power semiconductor device coupled between the second leads and having a control lead;
a driver comprising:
an upper transistor defining a first lead coupled to the upper terminal, a second lead, and a base;
a lower transistor defining a first lead coupled to the lower terminal, a second lead, and a base;
an upper gate-driver having a drive-in terminal, a drive terminal coupled to both the gate of the upper-cascode FET and the base of the upper transistor, and a sense terminal coupled to the second lead of the lower transistor, the upper gate-driver is configured to, responsive to assertion of its drive-in terminal, drive a reverse sense current through the lower transistor and the power semiconductor device;
the upper gate-driver configured to, responsive to an overcurrent condition detected using the reverse sense current, de-assert its drive terminal to make the upper-cascode FET and the upper transistor non-conductive;
a lower gate-driver having a drive-in terminal, a drive terminal coupled to both the gate of the lower-cascode FET and the base of the lower transistor, and a sense terminal coupled to the second lead of the lower transistor, the lower gate-driver is configured to, responsive to assertion of its drive-in terminal, drive a forward sense current through the upper transistor and power semiconductor device; and
the lower gate-driver configured to, responsive to an overcurrent condition detected using the forward sense current, de-assert its drive terminal to make the lower cascode FET and the lower transistor non-conductive.

14. The switch assembly of claim 13 wherein the power semiconductor device is a double-sided double-base bipolar junction transistor.

15. The switch assembly of claim 13 wherein the upper transistor is at least one selected from a group comprising: a junction transistor; an integrated gate bipolar junction transistor.

16. The switch assembly of claim 13 wherein the lower transistor is at least one selected from a group comprising: a junction transistor; an integrated gate bipolar junction transistor.

17. The switch assembly of claim 13 further comprising:
an overcurrent terminal defined by the upper gate-driver;
an overcurrent terminal defined by the lower gate-driver;
a controller coupled to the control input, the control lead of power semiconductor device, the drive-in terminals, and the overcurrent terminals, the controller configured to:
responsive to assertion of the control input and for a first applied voltage across the upper terminal and lower terminal, assert the drive-in terminals to arrange upper cascode FET and lower cascode FET for conduction of forward load current; and
responsive to assertion of the overcurrent terminal of the lower gate-driver, de-assert the drive-in terminals.

18. The switch assembly of claim 13 wherein the controller is further configured to:
responsive to assertion of the control input and for a second applied voltage across the upper terminal and lower terminal, opposite the first applied voltage, assert the drive-in terminals to arrange upper cascode FET and lower cascode FET for conduction of reverse load current; and
responsive to assertion of an overcurrent terminal of the upper gate-driver, de-assert the drive-in terminals.

19. The switch assembly of claim 13 wherein the upper cascode FET, the lower cascode FET, and the power semiconductor device are co-packaged.
